(19) United States
(12) Patent Application Publication
(10) Pub. No.: US 2023/0159322 A1
(43) Pub. Date: May 25, 2023

(54) MEMS DEVICE AND MANUFACTURING METHOD THEREOF

(71) Applicants: HYUNDAI MOTOR COMPANY, SEOUL (KR); KIA CORPORATION, SEOUL (KR)

(72) Inventors: Dae Sung Kwon, Seoul (KR); Il Seon Yoo, Suwon-si (KR); Jang Hyeon Lee, Gunpo-si (KR); Dong Gu Kim, Suwon-si (KR); Hyun Soo Kim, Yongin-si (KR)

(21) Appl. No.: 17/871,075

(22) Filed: Jul. 22, 2022

(30) Foreign Application Priority Data
Nov. 24, 2021 (KR) 10-2021-0163661

(51) Int. Cl. B81B 7/00

(52) U.S. Cl. CPC B81B 7/0096

(57) ABSTRACT

The present disclosure relates to a microelectromechanical systems (MEMS) device and method for manufacturing the same for improving the uniformity of temperature distribution in a heater unit, and the present disclosure discloses a MEMS device and method for manufacturing the same, including a heater unit that is formed on a substrate, and a dummy pattern unit that is formed in a remaining portion except for a portion where the heater unit is formed so as not to be electrically connected to the heater unit.

### CROSS REFERENCE TO RELATED APPLICATIONS

The present application claims priority to Korean Patent Application No. 10-2021-0163661, filed Nov. 24, 2021, the entire contents of which is incorporated herein for all purposes by this reference.

### BACKGROUND

### Field of the Disclosure

The present disclosure relates to a MEMS (microelectromechanical systems) device for improving uniformity of temperature distribution in a heater unit and a method for manufacturing the same.

### Description of the Related Art

MEMS heaters are widely used to manufacture low-cost gas sensors because they can be mass-produced through a batch process.

A conventional MEMS hydrogen sensor is composed of a MEMS heater, an insulating layer that protects the heater, and a catalyst that reacts with hydrogen.

The catalyst promotes oxidation with hydrogen, and Pt, Pd, etc., are used as the catalyst. The catalyst is heated using the MEMS heater to activate the catalyst.

When hydrogen and oxygen react through the heated catalyst, heat of reaction is generated, and the degree of reaction is measured by detecting the change in resistance of the heater.

On the other hand, a metal oxide-based gas sensor requires a high temperature of 300 to 400° C. for reaction, and research on the heater that can uniformly form such a temperature in a desired area is being conducted.

In order to minimize heat loss to a substrate and reduce power consumption for driving the heater, the heater is usually manufactured in the form of a membrane. In addition, in order to rapidly increase the temperature to a desired temperature and to form a uniform temperature distribution, a technique such as changing a heater design or adding a specific material and structure to the heater has been proposed.

For example, temperature uniformity may be improved by adding a heat dissipation layer having excellent thermal conductivity inside the substrate.

When the additional heat dissipation layer is formed, heat is evenly distributed over the area where the heat dissipation layer is formed to improve temperature uniformity. However, as the process of forming the heat dissipation layer is added, the manufacturing process becomes complicated and the thickness of the entire layer of the MEMS device becomes thick.

As another method for improving the uniformity of temperature, a technique for improving the uniformity of heat distribution in a single layer through a design change of the heater has been proposed.

However, since the linearity of the heater structure is deteriorated, it is difficult to use it as a sensor for monitoring the change in heater resistance itself, and the design becomes complicated.

The matters described as the background technology of the present disclosure are only for improving the understanding of the background of the present disclosure, and should not be taken as acknowledging that they correspond to the prior art already known to those of ordinary skill in the art.

### SUMMARY

The present disclosure has been devised to solve the above-described problems, and the object of the present disclosure is to provide a MEMS device for improving uniformity of temperature distribution in a heater and a method for manufacturing the same.

In order to achieve the above object, a MEMS sensor of the present disclosure is configured to include a heater unit that is formed on a substrate; and a dummy pattern unit that is formed in a remaining portion except for a portion where the heater unit is formed so as not to be electrically connected to the heater unit.

The dummy pattern unit may be formed in an empty space formed inside a pattern of the heater unit.

The dummy pattern unit may be formed of the same material as the heater unit.

The dummy pattern unit may be formed together in a process of forming the heater unit.

The dummy pattern unit may be formed on the same layer as the heater unit.

A hole may be formed in a portion of the substrate corresponding to the heater unit and the dummy pattern unit.

A method for manufacturing a MEMS device of the present disclosure includes a configuration in which a heater unit and a dummy pattern unit are formed on a substrate, while forming the dummy pattern unit in a remaining portion except for a portion where the heater unit is formed such that the dummy pattern unit is not electrically connected to the heater unit.

A method for manufacturing a MEMS device of the present disclosure includes the steps of forming a first insulating layer on a substrate, forming a heater unit and a dummy pattern unit on the first insulating layer while forming the dummy pattern unit in a remaining portion except for a portion where the heater unit is formed such that the dummy pattern unit is not electrically connected to the heater unit, forming a second insulating layer on the heater unit and the dummy pattern unit, and forming an electrode pad on the heater unit.

The dummy pattern unit may be formed together in a process of forming the heater unit.

A hole may be formed in a portion of the substrate corresponding to the heater unit and the dummy pattern unit.

Through the problem solving means of the present disclosure as described above, the dummy pattern unit is disposed in the empty space of the heater unit, so that the heat transfer occurs faster over the entire area of the membrane due to the lowered thermal resistance, and accordingly, the temperature difference between the central portion and the outer portion of the heater unit is reduced. As a result, an excellent temperature distribution in a wider area can be achieved, and the uniformity of the temperature distribution can be improved.

Further, in the process of depositing and patterning the heater unit, by depositing and patterning the dummy pattern unit together with the heater unit, the effect of improving the uniformity of the temperature distribution similar to that of adding the heat dissipation layer is obtained without a separate process such as adding a heat dissipation layer.

Furthermore, since the dummy pattern unit is formed on the same layer as the heater unit, there is an advantage of implementing a structure that improves the uniformity of the temperature distribution without changing the thickness of the entire MEMS device.

### BRIEF DESCRIPTION OF THE FIGURES

FIG. 1 is a view showing a shape of a MEMS device in which a heater unit and a dummy pattern unit are formed according to the present disclosure.

FIG. 2 is an exploded perspective view of a MEMS device according to the present disclosure.

FIGS. 3 and 4 are views showing a comparison of the temperature distribution according to whether or not a dummy pattern unit of the present disclosure is applied.

FIGS. 5A, 5B, 5C, 5D, 5E, and 5F are views explaining a method for manufacturing a MEMS device according to the present disclosure.

### DETAILED DESCRIPTION

Specific structural or functional descriptions of the embodiments of the present disclosure disclosed in the present specification or application are only exemplified for the purpose of describing the embodiments according to the present disclosure, and the embodiments according to the present disclosure may be implemented in various forms and should not be construed as being limited to the embodiments described in the present specification or application.

Since the embodiment according to the present disclosure can have various changes and various forms, specific embodiments are illustrated in the drawings and described in detail in the present specification or application. However, this is not intended to limit the embodiment according to the concept of the present disclosure with respect to a specific disclosed form, and should be understood to include all changes, equivalents or substitutes included in the spirit and scope of the present disclosure.

Terms such as first and/or second may be used to describe various elements, but the elements should not be limited by the terms. The above terms are used only for the purpose of distinguishing one element from another. For example, without departing from the scope of the present disclosure, a first element may be called a second element, and similarly the second component may also be referred to as the first component.

When a component is referred to as being “connected” or “contacted” to another component, it may be directly connected or contacted to the other component, but it should be understood that other components may exist in between. On the other hand, when it is mentioned that a certain element is “directly connected” or “directly contacted” to another element, it should be understood that no other element is present in the middle. Other expressions describing the relationship between elements, such as “between” and “immediately between” or “adjacent to” and “directly adjacent to”, etc., should be interpreted similarly.

The terms used herein are used only to describe specific embodiments, and are not intended to limit the present disclosure. The singular expression includes the plural expression unless the context clearly dictates otherwise. In the present specification, terms such as “comprise” or “have” are intended to designate that the described feature, number, step, operation, component, part, or a combination thereof exists, and it should be understood that it does not preclude the possibility of the existence or addition of one or more other features, numbers, steps, operations, elements, parts, or combinations thereof in advance.

Unless defined otherwise, all terms used herein, including technical and scientific terms, have the same meaning as commonly understood by one of ordinary skill in the art to which this disclosure belongs. Terms such as those defined in commonly used dictionaries should be interpreted as having meanings consistent with the context of the related art, and unless explicitly defined in the present specification, they are not to be interpreted in an ideal or excessively formal meaning.

A preferred embodiment of the present disclosure will be described in detail with reference to the accompanying drawings.

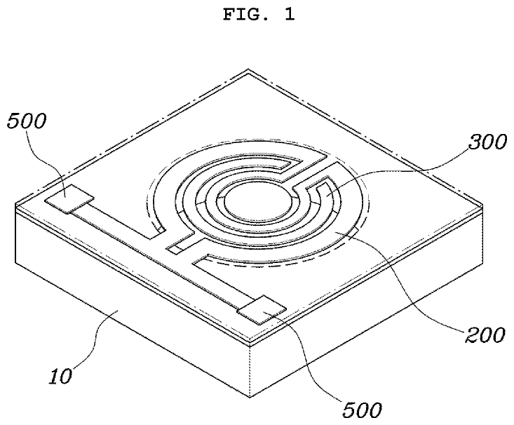

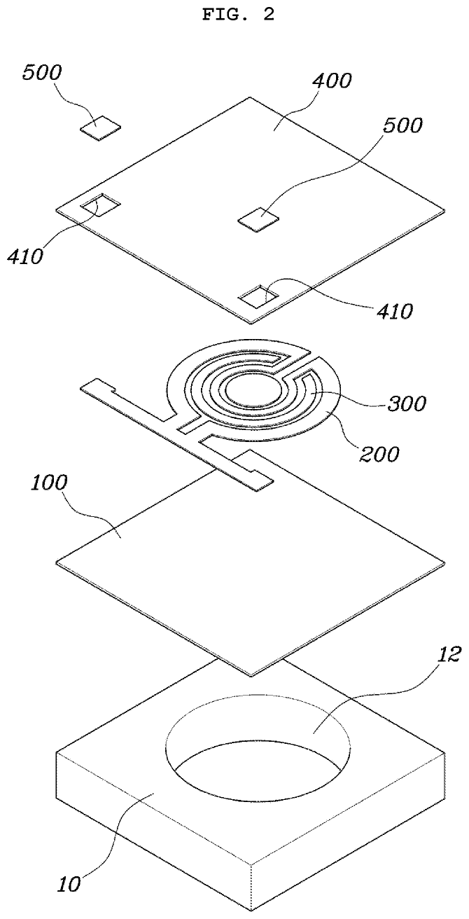

FIG. 1 is a view showing a shape of a MEMS device in which a heater unit 200 and a dummy pattern unit 300 are formed according to the present disclosure, and FIG. 2 is an exploded perspective view of a MEMS device according to the present disclosure.

Referring to the drawings, a MEMS device of the present disclosure is configured to include a heater unit 200 that is formed on a substrate 10, and a dummy pattern unit 300 that is formed in a remaining portion except for a portion where the heater unit 200 is formed so as not to be electrically connected to the heater unit 200.

Specifically, a first insulating layer 100 is deposited on the surface of the substrate 10 formed of a silicon material. The first insulating layer 100 may be deposited using a compound such as SiO₂ and Si₃N₄.

Then, a heater electrode is deposited and patterned as the heater unit 200 on the surface of the first insulating layer 100. For the heater electrode, a metal having a high melting point and good thermal conductivity, such as Pt and Mo, may be used.

At the same time, the dummy pattern unit 300 is deposited and patterned on the surface of the first insulating layer 100.

In particular, since the dummy pattern unit 300 is spaced apart so as not to be directly connected to the heater unit 200, it is not electrically connected to the heater electrode.

The dummy pattern unit 300 may be formed in an empty space created inside the pattern of the heater unit 200.

For example, as shown in FIG. 2, the pattern of the heater unit 200 is formed in a ‘Ω’ shape, and an empty space is formed inside the heater unit 200.

Accordingly, the dummy pattern part 300 is formed in a ‘C’ shape in the empty space in the heater unit 200.

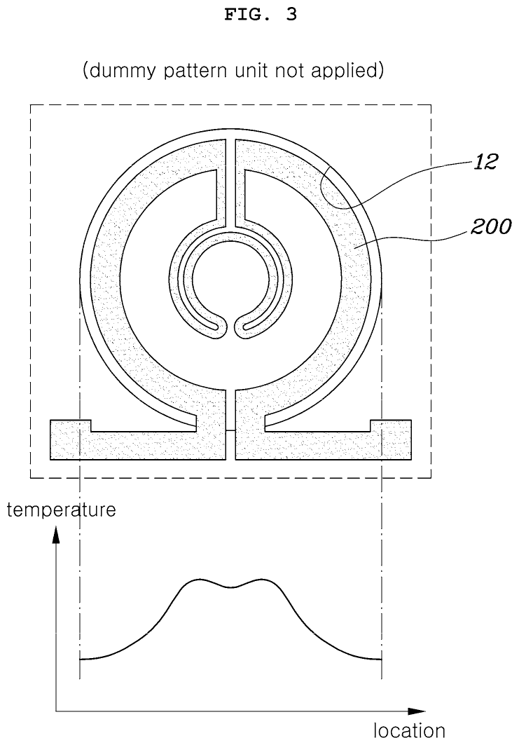

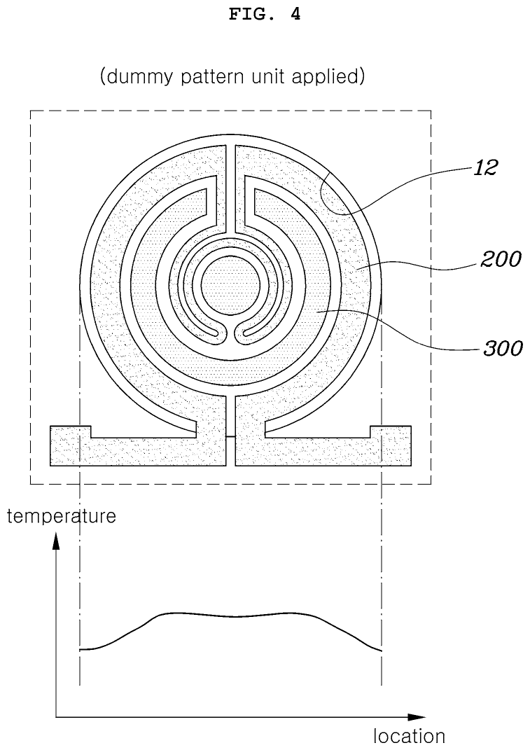

FIGS. 3 and 4 are views showing a comparison of the temperature distribution according to whether or not the dummy pattern unit 300 of the present disclosure is applied. By disposing the dummy pattern unit 300 in the empty space of the heater unit 200, the thermal resistance is lowered, which results in faster heat transfer across the entire area of the membrane.

Accordingly, although the temperature of the central portion of the heater unit 200 is decreased, the temperature difference between the central portion and the outer portion is reduced, thereby having a better temperature distribution in a wider area, and improving the uniformity of the temperature distribution.

In addition, in the present disclosure, the dummy pattern unit 300 may be formed of the same material as the heater unit 200.

For example, when the heater unit 200 is Pt, the dummy pattern unit 300 may be also formed by the application of Pt, and when the heater unit 200 is Mo, the dummy pattern unit 300 may be also formed of by the application of Mo.

Accordingly, the dummy pattern unit 300 may be formed together in the process of forming the heater unit 200.

That is, by depositing and patterning the dummy pattern unit 300 together with the heater electrode in the process of depositing and patterning the heater electrode, there is an effect of improving the uniformity of the temperature distribution similar to that of adding a heat dissipation layer, without an additional process such as adding the heat dissipation layer.

In addition, in the present disclosure, the dummy pattern unit 300 may be formed on the same layer as the heater unit 200.

That is, the dummy pattern unit 300 is formed together on the same layer as the heater electrode in the process of forming the heater electrode.

Accordingly, a structure for improving the uniformity of the temperature distribution may be implemented without changing the thickness of the entire MEMS device.

Meanwhile, in the present disclosure, a hole 12 may be formed in a portion of the substrate 10 corresponding to the heater unit 200 and the dummy pattern unit 300.

For example, when an insulating layer is formed on the upper and lower portions of the substrate 10, and the heater unit 200 and the dummy pattern unit 300 are formed at the upper center of the substrate 10, the hole 12 is formed in the center of the substrate 10 by removing the insulating layer formed on the lower surface of the substrate 10 through a deep reactive ion etching (DRIE) etching process.

Accordingly, as the heat of the heater unit 200 is thermally conducted through the substrate 10, heat loss can be minimized.

Meanwhile, in the method of manufacturing a MEMS device according to the present disclosure, as shown in FIG. 1, the heater unit 200 and the dummy pattern unit 300 are formed on the substrate 10, but the dummy pattern unit 300 may be formed in the remaining portion except for the portion where the heater unit 200 is formed so as not to be electrically connected to the heater unit 200.

Looking at the method of manufacturing the MEMS device step by step, the method is configured to include the steps of forming a first insulating layer 100 on the substrate 10, forming the heater unit 200 and the dummy pattern unit 300 on the first insulating layer 100 such that the dummy pattern unit 300 is formed in a remaining portion except for the portion where the heater unit 200 is formed so as not to be electrically connected to the heater unit 200, forming a second insulating layer 400 on the heater unit 200 and the dummy pattern unit 300, and forming an electrode pad 500 on the heater unit 200.

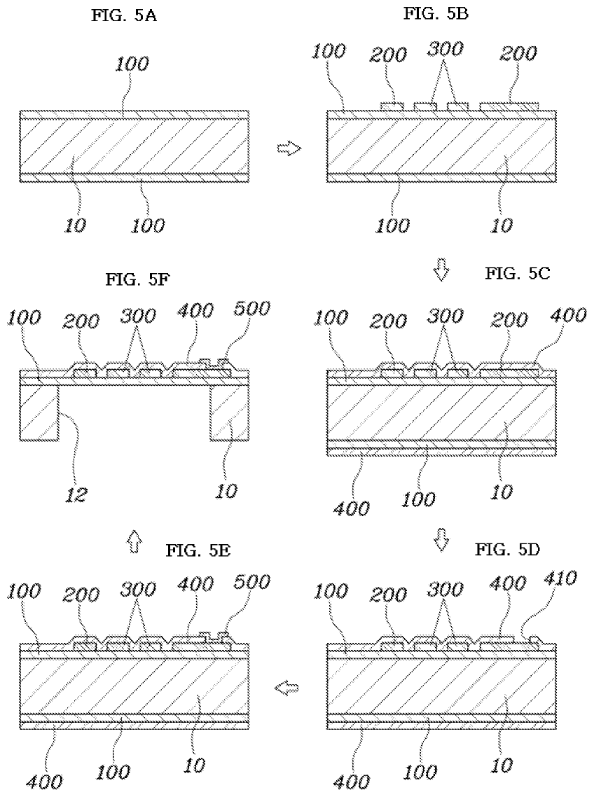

FIGS. 5A, 5B, 5C, 5D, 5E, and 5F are views explaining a method for manufacturing a MEMS device according to the present disclosure.

Referring to the drawings, the method for manufacturing the MEMS device will be described in detail. As shown in FIG. 5A, the first insulating layer 100 is formed by depositing on the upper and lower surfaces of the silicon substrate 10 using a compound such as SiO₂, Si₃N₄.

Then, as shown in FIG. 5B, the dummy pattern unit 300 is deposited and patterned together with the heater unit 200 made of a metal such as Pt and Mo on the surface of the first insulating layer 100 formed on the upper portion of the substrate 10.

Next, as shown in FIG. 5C, a second insulating layer 400 is deposited by using a compound such as SiO₂ and Si₃N₄ on the surface of the first insultation layer 100 and the upper surfaces of the pattered heater unit 200 and dummy pattern unit 300.

Through this, the heater unit 200 is protected and an insulating function is performed.

Here, when the first insulating layer 100 and/or the second insulating layer 400 are formed, the first insulating layer 100 and/or the second insulating layer 400 may be deposited in a multi-layered structure to prevent deformation of the membrane due to residual stress.

Thereafter, as shown in FIG. 5D, a via hole 410 is formed in the second insulating layer 400 corresponding to both ends of the heater unit 200.

Then, as shown in FIG. 5E, by depositing and patterning the electrode pad 500 of Al or Au in the via hole 410, the electrode pad 500 is wired to the heater unit 200.

Subsequently, as shown in FIG. 5F, the hole 12 is formed on the center of the substrate 10 where the heater unit 20 and the dummy pattern unit 300 are formed while the first insulating layer 100 and the second insulating layer 400 formed on the lower surface of the substrate 10 are removed through an etching process. Therefore, the heat conduction through the substrate 10 is prevented to minimize heat loss.

In addition, by additionally performing annealing heat treatment after the above-described deposition step, the performance of the heater unit 200 may be improved and the stress of the insulating layer may be relieved.

As described above, in the present disclosure, by arranging the dummy pattern unit 300 in the empty space of the heater unit 200, heat transfer occurs faster over the entire membrane area due to the lowered thermal resistance, and accordingly, the temperature difference between the central portion and the outer portion of the heater unit 200 is reduced, a better temperature distribution is obtained in a wider area, thereby improving the uniformity of the temperature distribution.

Furthermore, in the process of depositing and patterning the heater unit 200, by depositing and patterning the dummy pattern unit 300 together with the heater unit 200, there is the effect of improving the uniformity of the temperature distribution similar to that of adding a heat dissipation layer, without an additional process such as adding the heat dissipation layer.

In addition, since the dummy pattern unit 300 is formed together on the same layer as the heater unit 200, a structure for improving the uniformity of the temperature distribution without changing the thickness of the entire MEMS device is realized.

For reference, although in the method for manufacturing the MEMS device shown in FIGS. 5A, 5B, 5C, 5D, 5E, and 5F, it is described that after depositing the first insulating layer 100 and the second insulating layer 400 on both surfaces of the substrate 10, the first insulating layer 100 and the second insulating layer 400 are removed from the lower portion of the substrate 10 through an etching process, the first insulating layer 100 and the second insulating layer 400 may be deposited only on the upper surface of the substrate 10, and the insulating layer may not be formed on the lower surface of the substrate 10, depending on the method of depositing the insulating layer.

In this case, the process of removing the insulating layer from the lower portion of the substrate 10 may be omitted, and only the hole 12 may be formed in the center of the substrate 10.

On the other hand, although the present disclosure has been described in detail only with respect to the specific examples described above, it is obvious to those skilled in the art that various modifications and variations are possible within the scope of the technical spirit of the present disclosure, and it is natural that such variations and modifications belong to the appended claims.

1. A microelectromechanical systems (MEMS) device comprising:
a heater unit formed on a substrate; and
a dummy pattern unit formed in a remaining portion of the MEMS device, except for a portion where the heater unit is formed so as not to be electrically connected to the heater unit.

2. The MEMS device according to claim 1, wherein the dummy pattern unit is formed in an empty space inside a pattern of the heater unit.

3. The MEMS device according to claim 1, wherein the dummy pattern unit is formed of the same material as the heater unit.

4. The MEMS device according to claim 1, wherein the dummy pattern unit is formed together in a process of forming the heater unit.

5. The MEMS device according to claim 1, wherein the dummy pattern unit is formed on the same layer as the heater unit.

6. The MEMS device according to claim 1, wherein a hole is formed in a portion of the substrate corresponding to the heater unit and the dummy pattern unit.

7. A method for manufacturing a microelectromechanical systems (MEMS) device, in which a heater unit and a dummy pattern unit are formed on a substrate, while forming the dummy pattern unit in a remaining portion except for a portion where the heater unit is formed such that the dummy pattern unit is not electrically connected to the heater unit.

8. A method for manufacturing a microelectromechanical systems (MEMS) device, comprising the steps of:
forming a first insulating layer on a substrate;
forming a heater unit and a dummy pattern unit on the first insulating layer while forming the dummy pattern unit in a remaining portion except for a portion where the heater unit is formed such that the dummy pattern unit is not electrically connected to the heater unit;
forming a second insulating layer on the heater unit and the dummy pattern unit; and
forming an electrode pad on the heater unit.

9. The method for manufacturing the MEMS device according to claim 8, wherein the dummy pattern unit is formed together in a process of forming the heater unit.

10. The method for manufacturing the MEMS device according to claim 8, wherein a hole is formed in a portion of the substrate corresponding to the heater unit and the dummy pattern unit.
